(19) United States
(12) Patent Application Publication
(10) Pub. No.: US 2026/0082646 A1
(43) Pub. Date: Mar. 19, 2026

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yuta SATO, Himeji Hyogo (JP); Toru SHONO, Himeji Hyogo (JP); Koji ONISHI, Ibo Hyogo (JP)

(21) Appl. No.: 19/043,271

(22) Filed: Jan. 31, 2025

(30) Foreign Application Priority Data
Sep. 18, 2024 (JP) 2024-161247

(51) Int. Cl. H10D 62/10; H10D 30/01; H10D 30/66; H10D 64/23

(52) U.S. Cl. CPC H10D 62/127; H10D 30/0295; H10D 30/0297; H10D 30/668; H10D 64/2527

(57) ABSTRACT

According to one embodiment, a semiconductor device includes first and second electrodes, first to third semiconductor regions, and a gate electrode. The third semiconductor region includes a first portion in contact with the second semiconductor region and a second portion provided on the first portion. A width of the second portion is less than a width of the first portion. The second portion is in contact with a second insulating layer. A ratio of a second distance to a first distance is not less than 0.05 and not more than 0.22. The first distance is a distance in the first direction from an upper surface of the first portion to a lower end of the gate electrode. The second distance is a distance in the first direction from the upper surface of the first portion to an upper end of the gate electrode.

### CROSS-REFERENCE TO RELATED APPLICATIONS

This application is based upon and claims the benefit of priority from Japanese Patent Application No.2024-161247, filed on Sep. 18, 2024; the entire contents of which are incorporated herein by reference.

### FIELD

Embodiments described herein relate generally to a semiconductor device.

### BACKGROUND

Semiconductor devices such as metal oxide semiconductor field effect transistors (MOSFETs) are used for power conversion and other applications. For semiconductor devices, there is a need for technology that can suppress the occurrence of leakage currents.

### BRIEF DESCRIPTION OF THE DRAWINGS

FIG. 1 is a perspective cross-sectional view illustrating a portion of a semiconductor device according to an embodiment;

FIG. 2 is an enlarged cross-sectional view of a portion of FIG. 1;

FIGS. 3A and 3B are cross-sectional views illustrating a method for manufacturing the semiconductor device according to the embodiment;

FIGS. 4A and 4B are cross-sectional views illustrating the method for manufacturing the semiconductor device according to the embodiment;

FIGS. 5A and 5B are cross-sectional views illustrating the method for manufacturing the semiconductor device according to the embodiment;

FIGS. 6A and 6B are cross-sectional views illustrating the method for manufacturing the semiconductor device according to the embodiment;

FIG. 7 is a cross-sectional view illustrating the method for manufacturing the semiconductor device according to the embodiment;

FIGS. 8A and 8B are observation results of portions of a semiconductor device according to a reference example by a transmission electron microscope;

FIG. 9 shows experimental results of leakage currents in semiconductor devices; and

FIG. 10 is a table showing experimental results.

### DETAILED DESCRIPTION

According to one embodiment, a semiconductor device includes a first electrode, a first semiconductor region of a first conductivity type, a gate electrode, a second insulating layer, a second semiconductor region of a second conductivity type, a third semiconductor region of the first conductivity type, and a second electrode. The first semiconductor region is provided on the first electrode. The gate electrode is provided on the first semiconductor region via a first insulating layer. The second insulating layer is provided on the gate electrode. The second semiconductor region is provided on the first semiconductor region. The second semiconductor region faces the gate electrode via the first insulating layer in a second direction. The second direction is perpendicular to a first direction from the first electrode to the first semiconductor region. The third semiconductor region is provided on the second semiconductor region. The third semiconductor region includes a first portion and a second portion. The first portion is in contact with the second semiconductor region. The second portion is provided on the first portion. A length of the second portion in the second direction is less than a length of the first portion in the second direction. The second portion is in contact with the second insulating layer. A ratio of a second distance to a first distance is not less than 0.05 and not more than 0.22. The first distance is a distance in the first direction from an upper surface of the first portion to a lower end of the gate electrode. The second distance is a distance in the first direction from the upper surface of the first portion to an upper end of the gate electrode. The second electrode is provided on the second semiconductor region, the third semiconductor region, and the second insulating layer. The second electrode includes a contact portion that is in contact with a portion of the second semiconductor region and the first portion in the second direction.

Embodiments of the invention will now be described with reference to the drawings. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. In the drawings and the specification of the application, components similar to those described thereinabove are marked with like reference numerals, and a detailed description is omitted as appropriate.

In the following descriptions and drawings, notations of n⁺, n⁻ and p⁺, p represent relative levels of impurity concentrations in conductivity types. That is, the notation with “+” shows a relatively higher impurity concentration than an impurity concentration for the notation without any of “+” and “−”. The notation with “−” shows a relatively lower impurity concentration than the impurity concentration for the notation without any of them. These notations represent relative levels of net impurity concentrations after the mutual compensation of these impurities when respective regions include both of a p-type impurity and an n-type impurity.

The embodiments described below may be implemented by reversing the p-type and the n-type of the semiconductor regions.

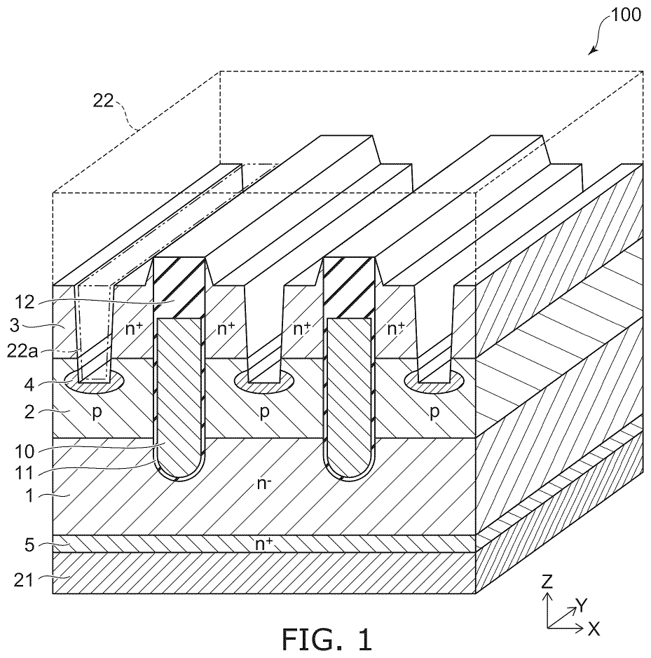

FIG. 1 is a perspective cross-sectional view illustrating a portion of a semiconductor device according to an embodiment.

The semiconductor device 100 according to the embodiment is a MOSFET. As shown in FIG. 1, the semiconductor device 100 includes an n⁻-type (a first conductivity type) drift region 1 (a first semiconductor region), a p-type (a second conductivity type) base region 2 (a second semiconductor region), an n⁺-type source region 3 (a third semiconductor region), a p⁺-type contact region 4 (a fourth semiconductor region), an n⁺-type drain region 5, a gate electrode 10, a first insulating layer 11, a second insulating layer 12, a drain electrode 21 (a first electrode), and a source electrode 22 (a second electrode). In FIG. 1, the source electrode 22 is shown with a dashed line and depicted as transparent.

An XYZ orthogonal coordinate system is used in the description of the embodiments. A direction from the drain electrode 21 toward the n⁻-type drift region 1 is taken as a Z-direction (a first direction); and two mutually-orthogonal directions perpendicular to the Z-direction are taken as an X-direction (a second direction) and a Y-direction (a third direction). In the description, the direction from the drain electrode 21 toward the n⁻-type drift region 1 is called “up/upward/above/higher than”, and the opposite direction is called “down/downward/below/lower than”. These directions are based on the relative positional relationship between the drain electrode 21 and the n⁻-type drift region 1, and are independent of the direction of gravity.

The drain electrode 21 is provided on the lower surface of the semiconductor device 100. The n⁺-type drain region 5 is provided on the drain electrode 21 and is electrically connected to the drain electrode 21. The n⁻-type drift region 1 is provided on the n⁺-type drain region 5. The n⁻-type drift region 1 is electrically connected to the drain electrode 21 via the n⁺-type drain region 5. The n-type impurity concentration in the n⁻-type drift region 1 is less than the n-type impurity concentration in the n⁺-type drain region 5.

The gate electrode 10 is provided on the n⁻-type drift region 1 via the first insulating layer 11. Multiple gate electrodes 10 are arranged in the X-direction, and the multiple gate electrodes 10 are separated from each other.

The p-type base region 2 is provided between two mutually-adjacent gate electrodes 10 among the multiple gate electrodes 10. The p-type base region 2 is located above the n⁻-type drift region 1. The p-type base region 2 and the gate electrode 10 are alternately arranged in the X-direction. The gate electrode 10 faces the p-type base region 2 via the first insulating layer 11 in the X-direction.

The n⁺-type source region 3 is provided on the p-type base region 2. The gate electrode 10 may face a portion of the n⁻-type drift region 1 and a portion of the n⁺-type source region 3 via the first insulating layer 11 in the X-direction.

The source electrode 22 is provided on the multiple gate electrodes 10, each via the second insulating layer 12. The source electrode 22 is located on the upper surface of the semiconductor device 100 and is electrically connected to the p-type base region 2 and the n⁺-type source region 3. The source electrode 22 is electrically isolated from the gate electrode 10 by the second insulating layer 12.

The source electrode 22 includes a contact portion 22a. The contact portion 22a extends downward, and is in contact with the n⁺-type source region 3 and a portion of the p-type base region 2 in the X-direction. The p⁺-type contact region 4 is provided between the p-type base region 2 and the contact portion 22a. The p-type impurity concentration in the p⁺-type contact region 4 is greater than the p-type impurity concentration in the p-type base region 2.

For example, the p-type base region 2, the n⁺-type source region 3, the p⁺-type contact region 4, the gate electrode 10, and the contact portion 22a each extend in the Y-direction. A pair of n⁺-type source regions 3, one p⁺-type contact region 4, and one contact portion 22a are provided on one p-type base region 2. The p-type base region 2, the n⁺-type source region 3, the p⁺-type contact region 4, the gate electrode 10, and the contact portion 22a are each provided in plurality along the X-direction, and they are arranged in a stripe pattern.

Operations of the semiconductor device 100 will now be described. A voltage that is not less than a threshold is applied to the gate electrode 10 in a state in which a positive voltage with respect to the source electrode 22 is applied to the drain electrode 21. As a result, a channel (an inversion layer) is formed in the p-type base region 2. Electrons flow from the source electrode 22 toward the n⁻-type drift region 1 via the channel; and the semiconductor device 100 is set to an on-state. Subsequently, when the voltage applied to the gate electrode 10 drops below the threshold, the channel in the p-type base region 2 disappears, and the semiconductor device 100 is set to an off-state.

Examples of the materials of the components will now be described. The n⁻-type drift region 1, the p-type base region 2, the n⁺-type source region 3, the p⁺-type contact region 4, and the n⁺-type drain region 5 include silicon, silicon carbide, gallium nitride, or gallium arsenide as a semiconductor material. When silicon is used as the semiconductor material, arsenic, phosphorus, or antimony can be used as the n-type impurity. Boron can be used as the p-type impurity. The gate electrode 10 includes a conductive material such as polysilicon, etc. The first insulating layer 11 and the second insulating layer 12 include insulating materials such as silicon oxide, silicon nitride, silicon oxynitride, etc. The drain electrode 21 and the source electrode 22 include metals such as titanium, gold, silver, tin, tungsten, or aluminum. The specific materials and compositions of the drain electrode 21 and the source electrode 22 are freely selected as long as the drain electrode 21 and the source electrode 22 can have ohmic contacts with the semiconductor regions.

Favorable ranges of the impurity concentrations of the semiconductor regions are as follows. The n-type impurity concentration in the n⁻-type drift region 1 is not less than 1.0×10¹⁶ atoms/cm³ and not more than 1.0×10¹⁸ atoms/cm³. The p-type impurity concentration in the p-type base region 2 is not less than 1.0×10¹⁷ atoms/cm³ and not more than 1.0×10¹⁹ atoms/cm³. The n-type impurity concentration in the n⁺-type source region 3 is not less than 5.0×10¹⁸ atoms/cm³ and not more than 5.0×10²⁰ atoms/cm³. The p-type impurity concentration in the p⁺-type contact region 4 is not less than 5.0×10¹⁸ atoms/cm³ and not more than 5.0×10²⁰ atoms/cm³. The n-type impurity concentration in the n⁺-type drain region 5 is not less than 1.0×10¹⁹ atoms/cm³ and not more than 1.0×10²¹ atoms/cm³.

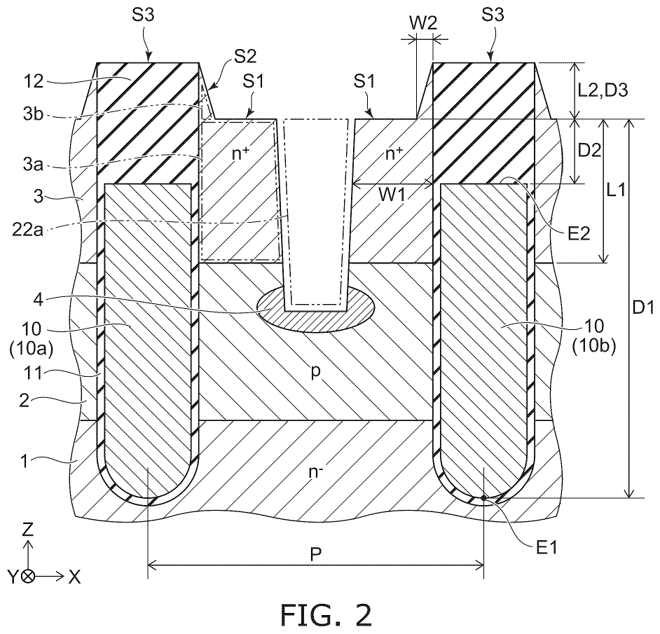

FIG. 2 is an enlarged cross-sectional view of a portion of FIG. 1.

As shown in FIG. 2, the n⁺-type source region 3 includes a first portion 3a and a second portion 3b. The first portion 3a is in contact with the p-type base region 2. The first portion 3a is located between the gate electrode 10 and the contact portion 22a, and between the second insulating layer 12 and the contact portion 22a in the X-direction. The second portion 3b is located on the first portion 3a and is in contact with the second insulating layer 12.

The width W2 of the second portion 3b is less than the width W1 of the first portion 3a. The “width” is the length in the X-direction. The first portion 3a has an upper surface S1. The upper surface S1 is in contact with the source electrode 22 in the Z-direction. The second portion 3b has an inclined surface S2. The inclined surface S2 is in contact with the source electrode 22 and is inclined with respect to the Z-direction.

In the semiconductor device 100 according to the embodiment, the ratio of a second distance D2 to a first distance D1 is not less than 0.05 and not more than 0.22. The first distance D1 is the distance in the Z-direction from the upper surface S1 to a lower end E1 of the gate electrode 10. The second distance D2 is the distance in the Z-direction from the upper surface S1 to an upper end E2 of the gate electrode 10.

Other examples of specific dimensional relationships are as follows. The width W2 of the second portion 3b is not more than 0.5 times the width W1 of the first portion 3a, and decreases toward the Z-direction. The width W2 may be not more than 0.4 times the width W1, and may be not more than 0.3 times the width W1. The width W1 is measured at the height of the upper end E2. The “height” is the position in the Z-direction. The width W2 is measured at the height of the boundary between the upper surface S1 and the inclined surface S2.

The inclination of the upper surface S1 with respect to the X-direction is not less than 0 degrees and not more than 15 degrees. The inclination of the inclined surface S2 with respect to the X-direction is more than 15 degrees and not more than 85 degrees. The inclination of at least a portion of the inclined surface S2 with respect to the X-direction is not less than 60 degrees.

The length L2 in the Z-direction of the second portion 3b is less than the length L1 in the Z-direction of the first portion 3a. The length L2 may be not more than 0.5 times the length L1, and may be not more than 0.3 times the length L1. The ratio of a third distance D3 to the first distance D1 is not less than 0.05 and not more than 0.25. The third distance D3 is the distance in the Z-direction from the upper surface S1 to an upper surface S3 of the second insulating layer 12.

The length in the Z-direction of the gate electrode 10 is not less than 550 nm and not more than 890 nm. This length corresponds to the distance in the Z-direction from the lower end E1 to the upper end E2. The first distance D1 is not less than 600 nm and not more than 1000 nm. The second distance D2 is not less than 30 nm and not more than 220 nm. The third distance D3 is not less than 50 nm and not more than 250 nm.

The pitch P of the multiple gate electrodes 10 is not less than 450 nm and not more than 650 nm. The pitch P corresponds to the distance between the center in the X-direction of a first gate electrode 10a and the center in the X-direction of a second gate electrode 10b. The first gate electrode 10a is one of the multiple gate electrodes 10. The second gate electrode 10b is another one of the multiple gate electrodes 10 and is adjacent to the first gate electrode 10a in the X-direction.

For example, the n-type impurity concentration in the second portion 3b is less than the n-type impurity concentration in the first portion 3a. Therefore, the electrical resistivity of the second portion 3b is greater than the electrical resistivity of the first portion 3a. Alternatively, the n-type impurity concentration in the second portion 3b may be the same as the n-type impurity concentration in the first portion 3a.

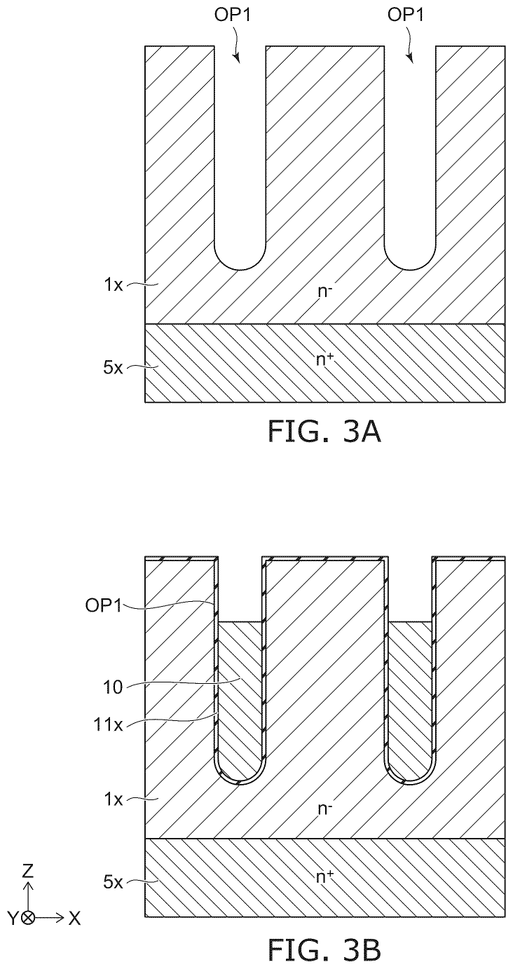

FIGS. 3A, 3B, 4A, 4B, 5A, 5B, 6A, 6B, and 7 are cross-sectional views illustrating a method for manufacturing the semiconductor device according to the embodiment.

First, a semiconductor substrate including an n⁺-type semiconductor layer 5x and an n⁻-type semiconductor layer 1x is prepared. The n⁻-type semiconductor layer 1x is provided on the n+-type semiconductor layer 5x. By photolithography and reactive ion etching (RIE), multiple openings OP1 are formed on the upper surface of the n⁻-type semiconductor layer 1x, as shown in FIG. 3A. The multiple openings OP1 are separated from each other in the X-direction, and each opening OP1 extends in the Y-direction.

By thermal oxidation, an insulating layer 11x is formed along the surface of the n⁻-type semiconductor layer 1x. A conductive layer is formed on the insulating layer 11x by chemical vapor deposition (CVD). The conductive layer includes, for example, polysilicon. The openings OP1 are filled with the conductive layer. The upper surface of the conductive layer is etched by wet etching. As a result, as shown in FIG. 3B, the conductive layer is separated into multiple parts, and the gate electrode 10 is formed inside each opening OP1.

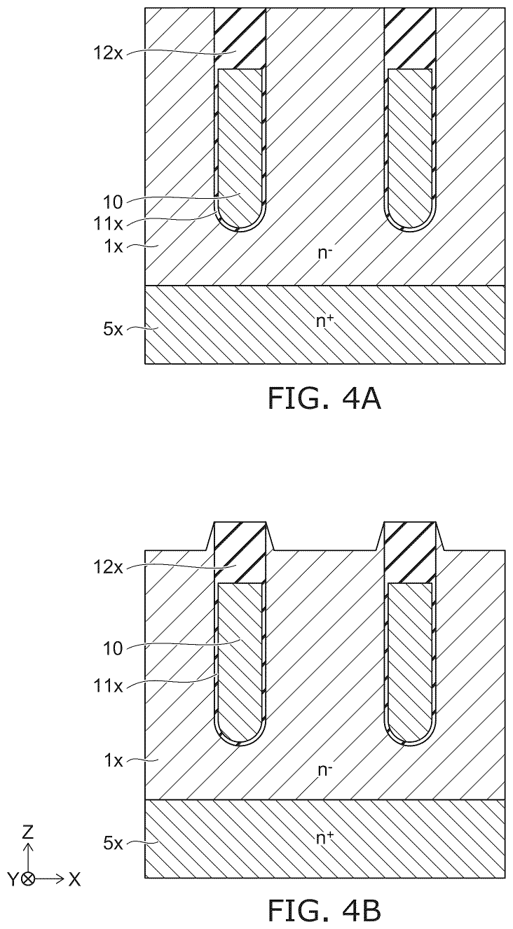

An insulating layer 12x is formed on the gate electrodes 10. The openings OP1 are filled with the insulating layer 12x. Chemical dry etching (CDE) is performed until the upper surface of the n⁻-type semiconductor layer 1x is exposed. As a result, as shown in FIG. 4A, a portion of the insulating layer 11x and a portion of the insulating layer 12x are removed, and the upper surface of the n⁻-type semiconductor layer 1x is exposed.

A portion of the n⁻-type semiconductor layer 1x between the insulating layers 12x is removed by CDE. In the CDE process, a gas with a higher etching rate for the semiconductor than for the insulating layer is selected. For example, HBr (hydrogen bromide) is used as the gas. When CDE is performed, there is a difference in etching rate between the portion in the vicinity of the insulating layer 12x and the portion away from the insulating layer 12x. In the vicinity of the insulating layer 12x, the n⁻-type semiconductor layer 1x is more difficult to remove. As a result, as shown in FIG. 4B, the upper surface of the portion in the vicinity of the insulating layer 12x is inclined. The upper surface of the portion in the vicinity of the insulating layer 12x is located higher than the upper surface of the portion away from the insulating layer 12x.

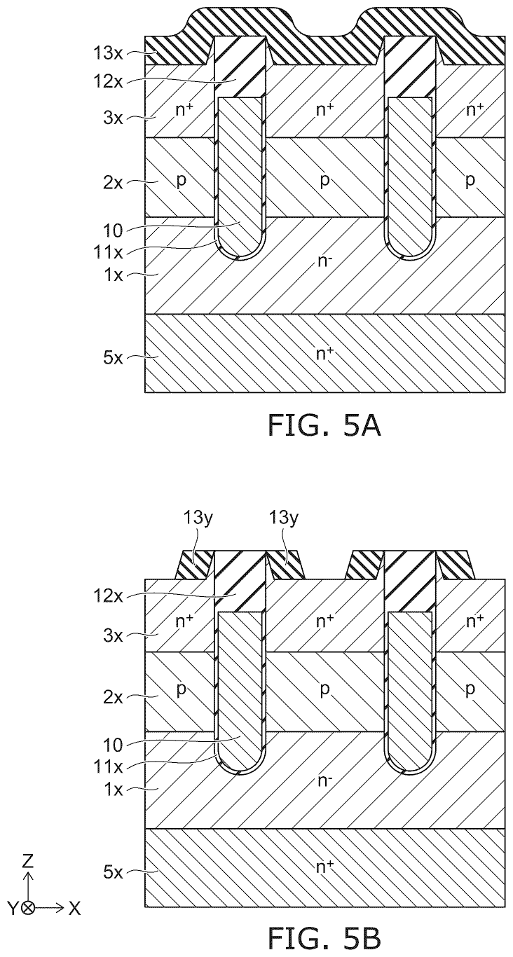

P-type impurities and n-type impurities are sequentially ion-implanted to the upper surface of the n⁻-type semiconductor layer 1x to form a p-type semiconductor region 2x and an n⁺-type semiconductor region 3x. As shown in FIG. 5A, an insulating layer 13x covering the n⁺-type semiconductor region 3x and the insulating layer 12x is formed by CVD. For example, the insulating layer 13x includes an insulating material such as silicon oxide or silicon nitride. As long as it can be used as a mask when etching the semiconductor layer as will be described later, the material of the insulating layer 13x can be changed as appropriate.

A portion of the insulating layer 13x is located on both ends in the X-direction of the n⁺-type semiconductor region 3x. Another portion of the insulating layer 13x is located on the center in the X-direction of the n⁺-type semiconductor region 3x. The thickness (the dimension in the Z-direction) of the portion of the insulating layer 13x is greater than the thickness of the other portion of the insulating layer 13x.

A portion of the insulating layer 13x is removed, by anisotropic etching, until a portion of the upper surface of the n⁺-type semiconductor region 3x is exposed. At this time, as shown in FIG. 5B, the thinner portion of the insulating layer 13x is removed, while the thicker portion of the insulating layer 13x remains. As a result, the insulating layer 13x remains on each end of the n⁺-type semiconductor region 3x, and other portions of the insulating layer 13x are removed. As a result, a mask 13y made from the insulating layer 13x is formed. The mask 13y covers the vicinity of the insulating layer 12x in the n⁺-type semiconductor region 3x. The center portion in the X-direction of the n⁺-type semiconductor region 3x is exposed.

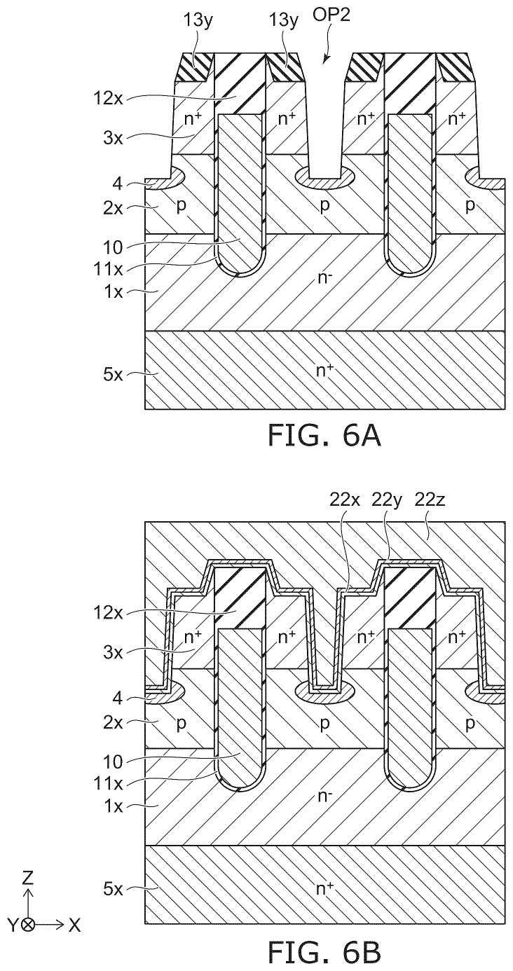

A portion of the n⁺-type semiconductor region 3x and a portion of the p-type semiconductor region 2x are removed by RIE using the mask 13y. As a result, an opening OP2 is formed. As shown in FIG. 6A, through the opening OP2, p-type impurities are ion-implanted to the bottom surface of the opening OP2 to form the p+-type contact region 4.

The mask 13y is removed. A metal layer 22x and a metal layer 22y are formed along the surface of the p-type semiconductor region 2x and the surface of the n⁺-type semiconductor region 3x by sputtering. The metal layer 22x includes titanium nitride. The metal layer 22y includes titanium. As shown in FIG. 6B, a metal layer 22z is formed on the metal layer 22y by sputtering. The metal layer 22z includes aluminum. The opening OP2 is filled with the metal layer 22z.

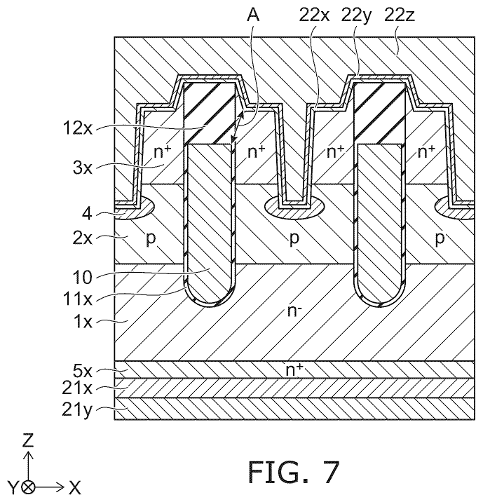

The lower surface of the n⁺-type semiconductor layer 5x is ground until the n⁺-type semiconductor layer 5x reaches a predetermined thickness. As shown in FIG. 7, a metal layer 21x is formed on the lower surface of the ground n⁺-type semiconductor layer 5x by sputtering. The metal layer 21x includes titanium. A metal layer 21y is formed on the metal layer 21x by plating. The metal layer 21y includes silver. Alternatively, the metal layer 21y may include a eutectic of gold and tin. According to the above steps, the semiconductor device 100 according to the embodiment is manufactured.

The n⁻-type semiconductor layer 1x shown in FIG. 7 corresponds to the n⁻-type drift region 1 shown in FIG. 1. The p-type semiconductor region 2x corresponds to the p-type base region 2. The n⁺-type semiconductor region 3x corresponds to the n⁺-type source region 3. The n⁺-type semiconductor layer 5x corresponds to the n⁺-type drain region 5. The insulating layer 11x corresponds to the first insulating layer 11. The insulating layer 12x corresponds to the second insulating layer 12. The metal layers 21x and 21y correspond to the drain electrode 21. The metal layers 22x to 22z correspond to the source electrode 22. A portion of the metal layer 22x, a portion of the metal layer 22y, and a portion of the metal layer 22z are located in the opening OP2. The portion of the metal layer 22x, the portion of the metal layer 22y, and the portion of the metal layer 22z correspond to the contact portion 22a.

Advantages of the embodiment will now be described.

The pitch P of the semiconductor device 100 is preferably small. The smaller the pitch P, the greater the number of gate electrodes 10 arranged per unit area. As a result, the channel density increases. As the channel density increases, the number of current paths in the on-state increases. Therefore, the on-resistance of the semiconductor device 100 can be reduced.

When manufacturing the semiconductor device 100 with a small pitch P, the misalignment of the contact portion 22a in the X-direction is preferably small. When the position of the contact portion 22a is shifted, the distance between one of the insulating layers 11x and the contact portion 22a becomes shorter. As shown in FIG. 6A, when the p⁺-type contact region 4 is formed, the p-type impurities diffuse in the vicinity of the insulating layer 11x more easily. As a result, the threshold voltage of the gate electrode 10 increases. In particular, when the pitch P is small, the distance between the insulating layer 11x and the contact portion 22a is small. Therefore, the increase in the threshold voltage due to the misalignment of the contact portion 22a is also large.

In the manufacturing method described above, as shown in FIG. 6A, the mask 13y is used when the opening OP2 is formed. The position of the mask 13y is determined based on the difference in the thickness of each portion of the insulating layer 13x. Specifically, the mask 13y is formed only on the side of the insulating layer 12x and is not formed at a position away from the insulating layer 12x. In other words, the position of the mask 13y is self-aligned based on the position of the insulating layer 12x. Therefore, even when the gap between the insulating layers 12x is narrow, the misalignment of the mask 13y can be suppressed. As a result, the misalignment of the opening OP2 formed using the mask 13y is also suppressed. It is possible to suppress the variation in the threshold voltage due to the misalignment of the contact portion 22a.

On the other hand, when the above manufacturing method is used, the height of a portion of the upper surface of the n⁺-type semiconductor region 3x is lowered by etching. As a result, the distance between the gate electrode 10 and the metal layer 22x, as indicated by arrow A in FIG. 7, becomes shorter. When the distance becomes short, a leakage current is more likely to occur between the gate electrode 10 and the source electrode 22. In order to suppress the occurrence of the leakage current, it is preferable to increase the distance between the gate electrode 10 and the source electrode 22. For example, by increasing the second distance D2 shown in FIG. 2, the occurrence of the leakage current can be suppressed.

According to examinations by the inventors of the present application, it was confirmed that the occurrence of the leakage current between the gate electrode 10 and the source electrode 22 can be suppressed by increasing the second distance D2. However, it was found that crystal defects are likely to occur in the n⁻-type drift region 1 in the vicinity of the bottom of the first insulating layer 11 when the second distance D2 is increased. The specific reason for this is unknown, but it is thought to be related to the stress applied to the semiconductor regions such as the n⁻-type drift region 1, the p-type base region 2, and the n⁺-type source region 3.

For example, when the second insulating layer 12 is formed, volume expansion occurs. In particular, when the second insulating layer 12 includes an oxide, the volume expansion becomes larger. Due to the volume expansion, a large tensile stress remains in the second insulating layer 12. As the second distance D2 becomes greater, the volume of the second insulating layer 12 increases, and the compressive stress applied from the second insulating layer 12 to the semiconductor regions increases. It is considered that crystal defects are likely to occur in the vicinity of the bottom of the first insulating layer 11 due to this stress. The occurrence of crystal defects leads to an increase in the leakage current between the drain electrode 21 and the source electrode 22 in the off-state. In addition, compressive stress is applied to the gate electrode 10 from the second insulating layer 12 as well. At this time, tensile stress is generated in the gate electrode 10. The tensile stress generated in the gate electrode 10 relieves the stress applied to the semiconductor regions. Therefore, in order to suppress the leakage current between the gate electrode 10 and the source electrode 22 while suppressing the occurrence of crystal defects, it is considered important to appropriately design the ratio D2/D1.

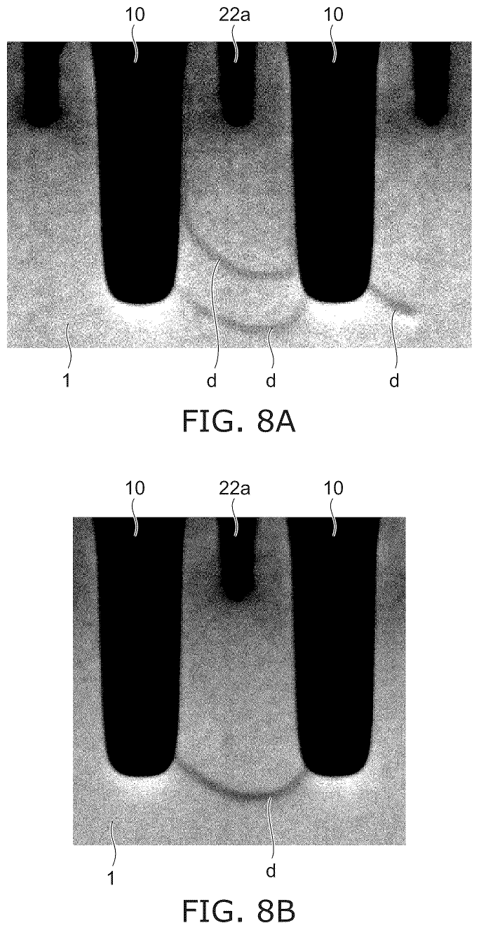

FIGS. 8A and 8B are observation results of parts of a semiconductor device according to a reference example by a transmission electron microscope.

In the semiconductor device according to the reference example, the ratio D2/D1 of the second distance D2 to the first distance D1 is 0.28. In this case, as shown in FIGS. 8A and 8B, it was confirmed that linear crystal defects d occurred in the n⁻-type drift region 1 between the lower ends of the gate electrodes 10.

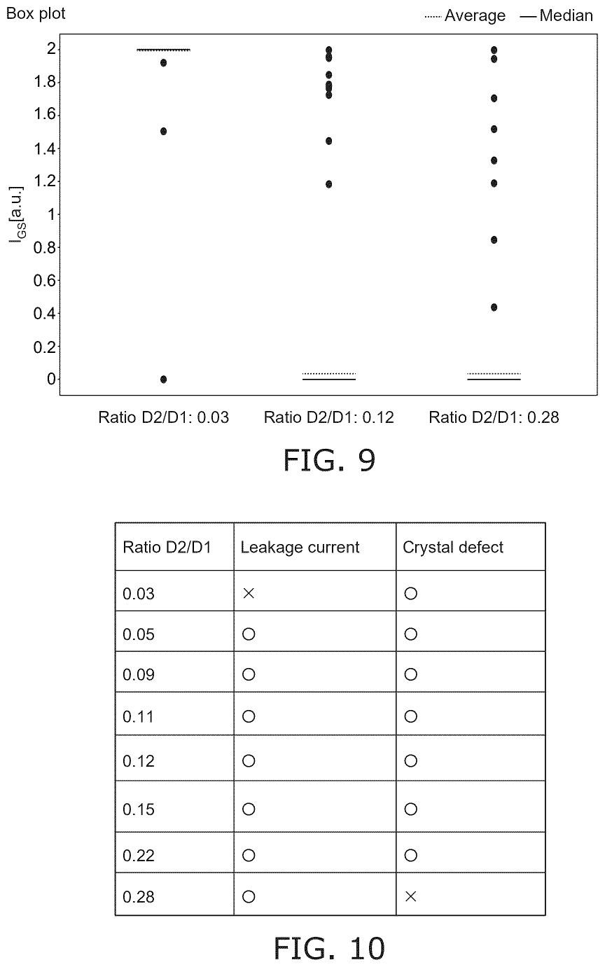

FIG. 9 shows experimental results of leakage currents in semiconductor devices.

In the experiment, three types of semiconductor devices with different ratios D2/D1 were prepared. For each ratio D2/D1, the leakage currents I_{GS} between the gate electrode 10 and the source electrode 22 in multiple semiconductor devices were measured. In the measurement of the leakage currents I_{GS}, the voltage V_{GS} between the gate electrode 10 and the source electrode 22 was set to 5V. The results are shown in FIG. 9. In FIG. 9, the vertical axis is shown in arbitrary units, and only data in which the leakage current I_{GS} exceeded the detection limit are plotted.

From the results shown in FIG. 9, when the ratio D2/D1 was 0.12 or 0.28, most of the measured leakage currents I_{GS} were below the detection limit, and the mean values and the median values were almost zero. Large leakage currents I_{GS} were measured in some semiconductor devices, but the number was negligible. On the other hand, when the ratio D2/D1 was 0.03, most of the measured leakage currents I_{GS} were very large, and the mean values and the median values exceeded the upper limit of measurement.

FIG. 10 is a table showing experimental results.

By repeating the same experiment while changing the ratio D2/D1, the presence or absence of crystal defects and the occurrence of leakage currents were investigated. Parameters other than the ratio D2/D1 such as the third distance D3, pitch P, and length in the Z-direction of the gate electrode 10 were designed within the above-described range. The results are shown in FIG. 10. In the experiment, the number of semiconductor devices in which the leakage current I_{GS} was 10 μA or less when the voltage V_{GS} was 5V was counted. The proportion of semiconductor devices counted to the total number of measured devices was calculated. In FIG. 10, the ratio D2/D1 with a proportion of 80% or more is evaluated as “good” and shown by a “circle”. The ratio D2/D1 with a proportion of less than 80% is evaluated as “defective” and is shown by a “cross”. In addition, in each ratio D2/D1, a part of the semiconductor devices was randomly selected from the semiconductor devices with low leakage currents I_{GS}. The cross-section of the selected semiconductor device was observed with a transmission electron microscope (TEM). In the TEM image, the observation area was randomly determined and at least twenty regions near the lower ends of the gate electrodes 10 were observed. In FIG. 10, the ratio D2/D1 in which no crystal defects were confirmed is evaluated as “good” and is shown by a “circle”. The ratio D2/D1 in which crystal defects were confirmed is evaluated as “defective” and is indicated by a “cross”. From the results shown in FIG. 10, it can be found that when the ratio D2/D1 is within the range of 0.05 to 0.22, the leakage current I_{GS} is low in many semiconductor devices, and the occurrence of crystal defects is sufficiently suppressed.

In the semiconductor device according to the embodiment, the ratio D2/D1 is within the range of 0.05 to 0.22. According to the embodiment, even when the pitch P is shortened, the occurrence of leakage current between the gate electrode 10 and the source electrode 22 can be suppressed, and the occurrence of leakage current between the drain electrode 21 and the source electrode 22 due to crystal defects can be suppressed. In other words, according to the embodiment, the on-resistance of the semiconductor device can be reduced by shortening the pitch P while suppressing the occurrence of these leakage currents.

Embodiments of the present invention are suitable for semiconductor devices in which a conductor (commonly referred to as a field plate electrode) is not provided below the gate electrode 10. Generally, the field plate electrode is located between the n—type drift region 1 and the gate electrode 10 in the Z-direction, and is electrically connected to the gate electrode 10 or the source electrode 22. When the field plate electrode is provided, it is necessary to form a thick insulating layer between the n⁻-type drift region 1 and the field plate electrode. Therefore, it becomes difficult to set the pitch of the gate electrodes 10 to between 450 nm and 650 nm. By applying the above configuration to a semiconductor device that is not provided with the field plate electrode, the on-resistance of the semiconductor device 100 can be effectively reduced while suppressing the increase in the threshold voltage of the gate electrode 10.

For example, according to the embodiment, the density of the crystal defects can be reduced to 0.06/um² or less. The density of crystal defects is measured by the following method. First, the semiconductor device is cut along the X-Z plane so that it passes through the center of the source electrode 22 in the X-Y plane. The cut surface is processed into a flat surface using a focused ion beam (FIB) or a similar method, and observed by TEM. The observation magnification is set between 5000 and 10000 times. The number of crystal defects in the observation area is counted. When the crystal defect is point-shaped, one point is counted as one crystal defect. As shown in FIGS. 8A and 8B, when the crystal defect is linear, the line of consecutive crystal defects is counted as one crystal defect. The density of crystal defects is calculated by dividing the number of counted crystal defects by the area of the observed semiconductor region.

In the n⁺-type source region 3, the n-type impurity concentration in the first portion 3a and the n-type impurity concentration in the second portion 3b may be the same or different. For example, the n-type impurity concentration in the second portion 3b is less than the n-type impurity concentration in the first portion 3a. This is because the n-type impurities in the second portion 3b diffuse more easily into the surroundings compared to those in the first portion 3a, since the width W2 of the second portion 3b is less than the width W1 of the first portion 3a. In this case, the electrical resistivity of the second portion 3b is greater than the electrical resistivity of the first portion 3a.

From the viewpoint of reducing the on-resistance, the second portion 3b is not preferable. On the other hand, the electrical resistivity of the second portion 3b is greater than the electrical resistivity of the first portion 3a. The voltage drop when the current flows through the second portion 3b is greater than the voltage drop when the current flows through the first portion 3a. For example, when the semiconductor device 100 is in a short-circuit state, a large current flows through the semiconductor device 100. At this time, the voltage drop increases because of the second portion 3b, which helps to suppress the current flowing through the semiconductor device 100. By providing the second portion 3b that is narrower than the first portion 3a, it is possible to reduce the current density in the short-circuit state while suppressing an increase in the on-resistance of the semiconductor device 100.

The embodiments of the present invention include the following features.

### Feature 1

A semiconductor device, comprising:
a first electrode;
a first semiconductor region of a first conductivity type provided on the first electrode;
a gate electrode provided on the first semiconductor region via a first insulating layer;
a second insulating layer provided on the gate electrode;
a second semiconductor region of a second conductivity type provided on the first semiconductor region, the second semiconductor region facing the gate electrode via the first insulating layer in a second direction that is perpendicular to a first direction from the first electrode to the first semiconductor region; a third semiconductor region of the first conductivity type provided on the second semiconductor region, the third semiconductor region including
   a first portion being in contact with the second semiconductor region, and
   a second portion provided on the first portion, a length of the second portion in the second direction being less than a length of the first portion in the second direction, the second portion being in contact with the second insulating layer,
a ratio of a second distance to a first distance being not less than 0.05 and not more than 0.22, the first distance being a distance in the first direction from an upper surface of the first portion to a lower end of the gate electrode, the second distance being a distance in the first direction from the upper surface of the first portion to an upper end of the gate electrode; and
a second electrode provided on the second semiconductor region, the third semiconductor region, and the second insulating layer, the second electrode including a contact portion that is in contact with a portion of the second semiconductor region and the first portion in the second direction.

### Feature 2

The semiconductor device according to feature 1, wherein
a length of the second portion in the second direction is not more than 0.5 times a length of the first portion in the second direction and decreases toward the first direction.

### Feature 3

The semiconductor device according to feature 1 or 2, wherein
an inclination of the upper surface of the first portion with respect to the second direction is not less than 0 degrees and not more than 15 degrees,
the second portion has an inclined surface, and
an inclination of the inclined surface with respect to the second direction is more than 15 degrees and not more than 85 degrees.

### Feature 4

The semiconductor device according to any one of features 1 to 3, wherein
the first distance is not less than 600 nm and not more than 1000 nm, and
the second distance is not less than 30 nm and not more than 220 nm.

### Feature 5

The semiconductor device according to any one of features 1 to 4, wherein
a length in the first direction from the lower end of the gate electrode to the upper end of the gate electrode is not less than 550 nm and not more than 890 nm.

### Feature 6

The semiconductor device according to any one of features 1 to 5, wherein
a ratio of a third distance to the first distance is not less than 0.05 and not more than 0.25, and
the third distance is a distance in the first direction from the upper surface of the first portion to an upper surface of the second insulating layer.

### Feature 7

The semiconductor device according to feature 6, wherein
the third distance is not less than 50 nm and not more than 250 nm.

### Feature 8

The semiconductor device according to any one of features 1 to 7, wherein
the gate electrode and the second semiconductor region are alternately provided in the second direction,
a plurality of the gate electrodes include a first gate electrode and a second gate electrode adjacent to each other in the second direction, and
a distance between a center of the first gate electrode in the second direction and a center of the second gate electrode in the second direction is not less than 450 nm and not more than 650 nm.

In the embodiments above, the relative levels of the impurity concentrations between the semiconductor regions can be confirmed using, for example, a scanning capacitance microscope (SCM). The carrier concentration in each semiconductor region can be considered to be equal to the activated impurity concentration in each semiconductor region. Accordingly, the relative levels of the carrier concentrations between the semiconductor regions also can be confirmed using SCM. The impurity concentration in each semiconductor region can be measured, for example, using secondary ion mass spectrometry (SIMS).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region of a first conductivity type provided on the first electrode;
a gate electrode provided on the first semiconductor region via a first insulating layer;
a second insulating layer provided on the gate electrode;
a second semiconductor region of a second conductivity type provided on the first semiconductor region, the second semiconductor region facing the gate electrode via the first insulating layer in a second direction that is perpendicular to a first direction from the first electrode to the first semiconductor region;
a third semiconductor region of the first conductivity type provided on the second semiconductor region, the third semiconductor region including
a first portion being in contact with the second semiconductor region, and
a second portion provided on the first portion, a length of the second portion in the second direction being less than a length of the first portion in the second direction, the second portion being in contact with the second insulating layer,
a ratio of a second distance to a first distance being not less than 0.05 and not more than 0.22, the first distance being a distance in the first direction from an upper surface of the first portion to a lower end of the gate electrode, the second distance being a distance in the first direction from the upper surface of the first portion to an upper end of the gate electrode; and
a second electrode provided on the second semiconductor region, the third semiconductor region, and the second insulating layer, the second electrode including a contact portion that is in contact with a portion of the second semiconductor region and the first portion in the second direction.

2. The semiconductor device according to claim 1, wherein
a length of the second portion in the second direction is not more than 0.5 times a length of the first portion in the second direction and decreases toward the first direction.

3. The semiconductor device according to claim 1, wherein
an inclination of the upper surface of the first portion with respect to the second direction is not less than 0 degrees and not more than 15 degrees,
the second portion has an inclined surface, and
an inclination of the inclined surface with respect to the second direction is more than 15 degrees and not more than 85 degrees.

4. The semiconductor device according to claim 1, wherein
the first distance is not less than 600 nm and not more than 1000 nm, and
the second distance is not less than 30 nm and not more than 220 nm.

5. The semiconductor device according to claim 1, wherein
a length in the first direction from the lower end of the gate electrode to the upper end of the gate electrode is not less than 550 nm and not more than 890 nm.

6. The semiconductor device according to claim 1, wherein
a ratio of a third distance to the first distance is not less than 0.05 and not more than 0.25, and
the third distance is a distance in the first direction from the upper surface of the first portion to an upper surface of the second insulating layer.

7. The semiconductor device according to claim 6, wherein
the third distance is not less than 50 nm and not more than 250 nm.

8. The semiconductor device according to claim 1, wherein
the gate electrode and the second semiconductor region are alternately provided in the second direction,
a plurality of the gate electrodes include a first gate electrode and a second gate electrode adjacent to each other in the second direction, and
a distance between a center of the first gate electrode in the second direction and a center of the second gate electrode in the second direction is not less than 450 nm and not more than 650 nm.
